(19) United States
(12) Patent Application Publication
(10) Pub. No.: US 2026/0319025 A1
(43) Pub. Date: Oct. 15, 2026

(54) CIRCUIT AND METHOD FOR DETECTING A MAGNETIC FIELD

(71) Applicant: Infineon Technologies AG, Neubiberg (DE)

(72) Inventors: Edwin Mario MOTZ, Wernberg (AT); Florian BRUGGER, Villach (AT)

(21) Appl. No.: 19/629,254

(22) Filed: Mar. 26, 2026

(30) Foreign Application Priority Data
Apr. 10, 2025 (DE) 102025114220.3

(51) Int. Cl. G01R 33/00; G01R 33/09

(52) U.S. Cl. CPC G01R 33/0029; G01R 33/098

(57) ABSTRACT

A circuit for detecting a magnetic field includes an xMR sensor bridge having a first and second output node in order to provide a differential sensor signal, wherein an average value of voltages of the output nodes to earth forms a first common operating point; a coupling capacitor stage that is coupled to the output nodes of the xMR sensor bridge; a processing circuit which is connected via the coupling capacitor stage to the xMR sensor bridge and is configured to provide a second, different common operating point; a clock unit which is configured to operate the processing circuit in at least two switching phases. Offset components of the processing circuit are detected and stored in a first switching phase at the second operating point and a component derived from the sensor signal, based on the second common operating point, is amplified or compared in a second switching phase.

### CROSS-REFERENCE TO RELATED APPLICATION

This application claims priority to Germany Patent Application No. 102025114220.3, filed Apr. 10, 2025, the contents of which are incorporated herein by reference in their entireties.

### TECHNICAL FIELD

The present disclosure relates generally to the field of magnetic sensors, in particular to magnetoresistive sensors (xMR sensors), which include, for example, tunnel magnetoresistance sensors (TMR sensors) which can be used to detect magnetic fields.

### BACKGROUND

Known xMR sensor systems may include a corresponding sensor circuit, for example a TMR bridge, with a subsequent processing circuit, for example an analogue processing circuit or an analogue-to-digital converter. However, such known solutions have certain technological limitations, in particular with regard to an achievable minimum supply voltage and the power consumption. The minimum supply voltage of these conventional sensors is typically limited by threshold and saturation voltages of the MOS transistors used, which can make it difficult to effectively reduce the power consumption and use particularly low supply voltages.

As a result, there is a need to improve such xMR sensor systems in order to both reduce the minimum required supply voltage and minimize the energy consumption.

### SUMMARY

This need is addressed by apparatuses and methods according to the independent claims. Advantageous developments emerge from the dependent claims.

According to a first aspect of the present disclosure, a circuit for detecting a magnetic field is proposed. The circuit includes an xMR sensor bridge having a first and second output node in order to provide a differential sensor signal, wherein an average value of voltages of the output nodes to earth forms a first common operating point. This means that the circuit contains an xMR sensor bridge that has two output nodes. A differential sensor signal is available between these output nodes, e.g., a useful signal is represented by a voltage difference between these two nodes. At the same time, both output nodes each have a specific voltage, measured against earth (reference potential). The arithmetic average value of these two voltages relative to earth in this case defines a so-called common mode voltage, also referred to as a common operating point. The common mode voltage thus represents a reference point (common operating point) around which the two output voltages are symmetrical. It thus forms a reference from which the differential sensor signal can be evaluated or further processed.

In the context of the present disclosure, an xMR sensor bridge is understood as meaning a bridge circuit which can be configured as a half-bridge or full bridge and in which at least one bridge branch includes a magnetoresistive resistor (xMR resistor). The remaining bridge elements can also be configured as xMR resistors or as ohmic reference resistors (e.g., polysilicon resistors). Arranging the xMR resistors within the bridge circuit makes it possible to generate a differential sensor signal that is dependent on the magnetic field.

The circuit also includes a coupling capacitor stage that is coupled to the output nodes of the xMR sensor bridge. This means that, in addition to the sensor bridge, there is a further circuit stage that uses capacitors for coupling. This stage is referred to as the coupling capacitor stage and is electrically connected to the two output nodes of the xMR sensor bridge. The coupling capacitor stage is used to separate DC voltage components from the sensor signal or to transmit the sensor signal to a subsequent processing circuit, where undesirable influences such as DC voltage shifts or offset voltages can be reduced or eliminated.

The circuit further includes a processing circuit which is connected via the coupling capacitor stage to the xMR sensor bridge and is configured to provide a second, different common operating point in order to achieve a function of the circuit at a minimum supply voltage. This means that the circuit additionally has an analogue processing circuit which is connected to the xMR sensor bridge via the aforementioned coupling capacitor stage. This processing circuit provides a second common operating point which differs from the first operating point (e.g., the common mode voltage of the sensor bridge). Selecting this second operating point makes it possible for the entire circuit to operate reliably even at a particularly low supply voltage. Adjusting the operating point thus makes it possible to optimize the power consumption and supply voltage of the circuit.

The circuit further includes a clock unit which is configured to operate the processing circuit in at least two switching phases, wherein offset components of the processing circuit are detected and stored in a first switching phase at the second operating point and a component derived from the sensor signal, based on the second common operating point, is amplified or compared in a second switching phase. This means that the circuit contains an additional clock unit that controls the processing circuit in at least two successive operating phases. In the first phase of this mode of operation, offset components of the processing circuit, e.g., undesirable voltage deviations that do not originate from the sensor signal, are measured and stored at the second common operating point. In the subsequent second phase, the actual signal component, which is generated by the sensor signal and fluctuates as an AC voltage around the second common operating point, is processed. This processing is carried out by either amplifying the signal or comparing it with a predefined threshold value. The aim of this two-phase procedure is to eliminate interfering offset components and thus enable more accurate and more reliable signal evaluation.

According to some example implementations, the processing circuit is configured to provide a lower second common operating point. This means that the processing circuit can be configured such that the second common operating point is at a different voltage level than the first common operating point. In other words, the processing circuit sets the reference point, around which the sensor signal is processed, to a different voltage level than the original operating point of the xMR sensor bridge. This enables the entire circuit to be operated efficiently with a further reduced supply voltage.

According to some example implementations, the processing circuit includes at least one of the following circuits:
a comparator,
an amplifier,
an analogue-to-digital converter, or
a voltage-controlled or current-controlled oscillator.

This means that, according to some designs, the processing circuit may contain at least one specific type of circuit. This could be, for example, a comparator that compares two voltages, an amplifier that amplifies the sensor signal, an analogue-to-digital converter that converts the analogue sensor signal into digital values, or a voltage-controlled or current-controlled oscillator that converts a sensor signal into a frequency or clock. The processing circuit is therefore not limited to a specific type of circuit, but may include one or more of these components depending on the desired application.

According to some example implementations, the processing circuit includes an auto-zeroing comparator, wherein, in the first switching phase (auto-zero phase), an offset of the processing circuit is detected and stored via capacitances integrated in the coupling capacitor stage, and, in the second switching phase (comparison phase), the component derived from the sensor signal is compared after subtracting the stored offset. This means that, in certain designs, the processing circuit may contain a so-called auto-zero comparator which is operated in two successive phases. In the first phase, the so-called auto-zero phase, the comparator detects and stores its own offset (an unwanted internal voltage deviation) using capacitors integrated in the coupling capacitor stage. In the subsequent second phase, the comparison phase, the component of the sensor signal is compared with a reference value. This takes into account and subtracts the previously stored offset, thus making the comparison more accurate and less prone to interference. This method thus improves the accuracy of the processing circuit, since interfering offset voltages are largely eliminated.

According to some example implementations, the processing circuit includes an auto-zeroing amplifier, wherein an offset of the amplifier is detected and stored in the first switching phase, and the sensor signal is output with an offset-corrected gain in the second switching phase. The auto-zeroing amplifier also operates in two temporally separated phases. During the first phase (auto-zero phase), the internal offset of the amplifier, e.g., an interfering internal voltage deviation, is detected and stored. In the subsequent second phase, the actual sensor signal is then amplified and output, with the previously stored offset being taken into account and compensated for. This method means that the sensor signal is amplified more precisely, since interfering offset components are effectively corrected.

According to some example implementations, the processing circuit is configured according to a correlated double sampling (CDS) method, wherein, in the first switching phase, a first sample of the sensor signal including the offset of the processing circuit is captured, in the second switching phase, a second, inverted sample of the signal including the offset of the processing circuit is captured, and an amplified, offset-adjusted sensor signal is generated by forming a difference between the samples. The processing can be carried out in two successive switching phases: In the first switching phase, a first sample of the sensor signal is recorded and contains both the actual sensor signal and unwanted offset components of the circuit. In the second switching phase, a second sample is captured, in which the sensor signal is inverted (with a reversed sign), but also including the same offset components of the circuit. By subsequently forming the difference between these two recorded values, the offset components are effectively eliminated. This ultimately generates a sensor signal that is both amplified and cleaned of interfering offset influences, thus making it possible to increase the signal capture accuracy.

According to some example implementations, the circuit further includes an additional clock unit which is configured to switch the xMR sensor bridge and/or the processing circuit between an active and an inactive state in a duty cycle mode. The additional clock unit is thus configured such that it cyclically switches either the xMR sensor bridge or the processing circuit (or both) back and forth between an active and an inactive operating state. This cyclic mode of operation, also referred to as “duty cycle mode”, means that the corresponding circuit components do not remain permanently switched on, but are only activated temporarily. This can reduce the average power consumption of the circuit, which can lead to significant energy savings, in particular in applications with a limited energy supply, for example in battery-powered systems.

According to some example implementations, the processing circuit includes a resistance network and/or current sources connected in parallel. This means that, in certain designs, the processing circuit may be configured such that it includes a network of resistors and/or a plurality of current sources connected in parallel. In particular, these components are used to set the aforementioned second common operating point. Using a resistance network or current sources connected in parallel makes it possible to set the second common operating point of the circuit precisely and stably to a desired voltage level which is typically lower than the first operating point. This enables an optimized function of the circuit with a reduced supply voltage, thereby improving the efficiency and accuracy of the sensor signal processing.

According to some example implementations, the processing circuit includes a switched capacitance network. A switched capacitance network, also known as a “switched capacitor network”, is a circuit arrangement of capacitors and switches that are switched at defined intervals of time. Cyclic switching of the capacitors between different switching states makes it possible to transfer charges in a targeted manner, to store voltages and to compensate for offset voltages. In particular, a switched capacitance network can be used to flexibly set and precisely stabilize the second common operating point of the circuit. Using targeted switching and charge transfer, this operating point can be brought to a desired voltage level which differs from the original (first) operating point of the sensor bridge—for example to a lower voltage level. This makes it possible to operate the processing circuit effectively even at very low supply voltages and to simultaneously compensate for offset voltages and improve the accuracy and stability of the sensor signal processing.

According to some example implementations, the processing circuit includes a network in order to set the second common operating point to a value that is below or above the first common operating point of the xMR sensor bridge. In order to set the second common operating point to a lower value than the first common operating point (common mode voltage of the xMR sensor bridge) using a network, the network is typically configured such that it discharges voltages to earth or provides a reference voltage closer to earth potential. Specifically, this can be carried out, for example, using a resistance network in which use is made of a voltage divider that reduces the common mode voltage. Alternatively, it can also be a switched capacitance network that transfers charges to a lower voltage level and thus lowers the operating point. Conversely, the network must be configured for a higher second common operating point such that it provides a voltage that is above the first common operating point. This can also be achieved, for example, using a suitable resistance network in which a voltage divider with a higher reference voltage is used. Alternatively, it is also possible to use current sources which supply current from a higher supply voltage and thus shift the operating point to a higher voltage level. This therefore means that the network can either be configured such that it raises the second common operating point to a higher level using a targeted supply of current or voltage or lowers the operating point to a lower level using a targeted discharge of charge or voltage.

According to some example implementations, the coupling capacitor stage has a first and second coupling capacitor each switchably coupled to outputs of the xMR sensor bridge, wherein, in the first switching phase, a first electrode of a coupling capacitor is connected to an output of the xMR sensor bridge and a second electrode of the coupling capacitor is connected to an output of the processing circuit, wherein, in the second switching phase, the second electrode of the coupling capacitor is coupled to an input of the processing circuit. This means that, in certain designs, the coupling capacitor stage consists of two capacitors each switchably connected to the two output nodes of the xMR sensor bridge. In the first switching phase, each capacitor is connected in such a way that one electrode of the respective capacitor is coupled to an output of the xMR sensor bridge, whereas the other electrode of the capacitor is simultaneously connected to an output of the processing circuit. In the second switching phase, the second electrode of the respective capacitor is then disconnected from this output and instead coupled to an input of the processing circuit. This alternating coupling of the electrodes makes it possible to first record and buffer certain voltages (such as offset voltages) in order to then, in the second phase, provide the sensor signal to the processing circuit precisely and in a form cleaned of offset components. This improves the accuracy of the entire sensor signal processing.

According to some example implementations, the processing circuit includes a reference device which, in the first switching phase, assigns a reference voltage level to a coupling capacitor, which voltage level is different from the common mode voltage of the xMR sensor bridge. This means that, in some variants, the processing circuit can additionally contain a so-called reference device. This reference device assigns a defined reference voltage to one of the coupling capacitors during the first switching phase. This reference voltage specifically differs from the common mode voltage of the xMR sensor bridge. This means that the coupling capacitor is initially set to a voltage other than that normally applied to the outputs of the sensor bridge. This specific voltage specification creates a reference which is then used to set the second common operating point and thus optimize the circuit, for example, for a lower supply voltage and a higher signal quality.

According to some example implementations, the reference device has an electrical resistor which is coupled via a first connection to the coupling capacitor and to an output of the processing circuit and is coupled via a second connection to earth. This means that, in certain designs, the aforementioned reference device can be configured as a simple electrical resistor. This resistor is connected, on the one hand, via a first connection to the coupling capacitor and to an output of the processing circuit. The second connection of the resistor is connected directly to earth. This arrangement causes the resistor to generate a defined reference voltage level by allowing electrical charge to flow specifically to earth via the resistor. In this way, a precise second common operating point is set that differs from the original common mode voltage of the xMR sensor bridge and may be at a lower voltage level, for example.

According to some example implementations, the xMR sensor bridge, the coupling capacitor stage and the processing circuit are monolithically integrated. This means that, in certain variants, the xMR sensor bridge, the coupling capacitor stage and the processing circuit can be manufactured together on a single semiconductor chip. In other words, all these components can be on a common substrate and can be manufactured together in a continuous production process. Such monolithic integration reduces parasitic effects, increases the signal quality, and makes it possible to realize the circuit in a more compact, more reliable and more cost-effective manner.

According to some example implementations, the circuit is manufactured in a complementary metal-oxide-semiconductor (CMOS) technology. This means that, in certain variants, the circuit can be produced using a CMOS semiconductor technology. CMOS stands for “Complementary Metal Oxide Semiconductor” and refers to a common technology for producing integrated circuits that is characterized in particular by low energy consumption, high integration density and low production costs. The use of a CMOS technology thus makes it possible to realize the circuit in a particularly energy-efficient, cost-effective and compact manner. In addition, CMOS technology supports the manufacturing of the aforementioned components (such as xMR sensor bridge, coupling capacitor stage and processing circuit) in a common, monolithic design.

According to some example implementations, the xMR sensor bridge is configured as a TMR sensor bridge. This means that, in some design variants, the xMR sensor bridge can be specifically realized as a tunnel magnetoresistance sensor bridge (TMR sensor bridge). In other words, these variants are not generally any magnetoresistive sensor bridge, but rather specifically a bridge circuit that uses TMR elements. This TMR sensor bridge is based on the tunnel effect in magnetic materials and is distinguished by a particularly high sensitivity to magnetic fields and a favourable energy efficiency. This makes the TMR bridge particularly suitable for applications in which a high sensitivity and low power consumption are required.

According to some example implementations, a supply voltage of the circuit is less than or equal to 1.1 V. This means that the circuit in certain design variants can be operated with a supply voltage whose level is at most 1.5 volts. In other words, the circuit is configured such that it can use particularly low supply voltages of at most 1.1 volts. This low operating voltage is advantageous for applications with a limited energy supply, such as battery-powered devices or energy-efficient sensors, since this can both reduce the power consumption and extend the battery service life.

According to a further aspect of the present disclosure, a method for detecting a magnetic field using an xMR sensor bridge is proposed. The method includes tapping off first and second sensor output signals at outputs of the xMR sensor bridge, capacitively decoupling a common mode voltage of the sensor output signals via at least two coupling capacitors, supplying the decoupled signals to a processing circuit which is operated in at least two switching phases, and setting a common mode voltage at the input and output of the coupling capacitors in a first switching phase which differs from the common mode voltage of the xMR sensor bridge.

Thus, the output signals from the sensor bridge are first tapped off at two separate output points. These signals have a common voltage component, the so-called common mode voltage. In order to be able to carry out the subsequent processing more precisely, this common mode voltage is separated from the sensor signals by at least two coupling capacitors (“capacitively decoupled”). The signals decoupled in this way are then supplied to a processing circuit which operates in at least two successive operating phases. In the first of these switching phases, a new common mode voltage is specifically set at both the input and the output of the coupling capacitors and differs deliberately from the original common mode voltage of the sensor bridge. This procedure allows targeted adjustment and optimization of the operating point in order to thereby improve the processing of the sensor signals at a particularly low supply voltage and reduced power consumption.

According to a further aspect of the present disclosure, a circuit for detecting a magnetic field is proposed. The circuit includes an xMR sensor bridge having a first and a second output for providing a sensor output signal. The circuit includes at least two decoupling capacitors each switchably coupled to the outputs of the xMR sensor bridge. The circuit includes an analogue processing circuit that is connected to the outputs of the xMR sensor bridge via the decoupling capacitors. The circuit includes at least one clock device for operating the analogue processing circuit in at least two switching phases, wherein the analogue processing circuit is configured to set a voltage differing from a common mode voltage of the xMR sensor bridge at the decoupling capacitors in a first switching phase.

According to some example implementations, the analogue processing circuit is configured to amplify the sensor signal transmitted by the decoupling capacitors and/or to compare it with a comparison or reference signal in the second switching phase, wherein the voltage potential set at the decoupling capacitors in the first switching phase and differing from the common mode voltage of the xMR sensor bridge is used as a means for achieving a minimum supply voltage.

### BRIEF DESCRIPTION OF THE FIGURES

Some examples of apparatuses and/or methods are explained in more detail below merely by way of example with reference to the accompanying figures, in which:

FIG. 1 shows a block diagram of a circuit for detecting a magnetic field, having an xMR sensor bridge, a coupling capacitor stage, a processing circuit and a clock unit;

FIG. 2 shows an auto-zero comparator circuit with a switchable coupling capacitor stage, in which the sensor signal is processed over two phases and is offset-compensated;

FIG. 3 shows a variant with switching logic internally integrated in a TMR bridge for inverting the voltage or current supply of the sensor bridge and the sensor signal and for offset compensation without additional signal line switching;

FIG. 4 shows a common source pseudo-differential architecture of the processing circuit with a modified for reducing the minimum supply voltage;

FIG. 5 shows a circuit with a multi-stage amplifier cascade for increasing the gain and a reference voltage divider for setting a defined switching threshold and auto-zeroing;

FIG. 6 shows a differential dual sensor structure with two TMR bridges and CDS technology for precise offset compensation and interference suppression at a low supply voltage;

FIG. 7 shows an example implementation with four-phase control and superimposed chopper technology for further reducing offset and noise;

FIG. 8A shows an auto-zero comparator with OTA-controlled output common mode and decoupled inputs via coupling capacitors;

FIG. 8B shows a simplified version without common mode control, in which the output common mode is defined via load resistors;

FIG. 8C shows a variant with current sources parallel to the load resistors for reducing the output voltage and the minimum supply voltage;

FIG. 8D shows a schematic representation of a multi-stage, differential amplifier circuit with a downstream latch;

FIG. 9A shows a processing circuit with a voltage-dividing resistance structure for lowering the input operating point and thus the supply voltage; and

FIG. 9B shows a combination of a voltage divider and parallel current sources for simultaneously increasing the gain and reducing the supply voltage.

### DESCRIPTION

Some examples are now described in more detail with reference to the accompanying figures. However, further possible examples are not restricted to the features of these implementations that are described in detail. These may include modifications of the features, as well as equivalents and alternatives to the features. Furthermore, the terminology used herein to describe specific examples should not be restrictive for further possible examples.

The same or similar reference signs relate throughout the description of the figures to the same or similar elements or features, which may each be implemented identically or else in a modified form, while providing the same or a similar function. In the figures, the thicknesses of lines, layers and/or regions may also be exaggerated for clarification.

When two elements A and B are combined using an “or”, this is to be understood as meaning that all possible combinations are disclosed, that is to say only A, only B, and also A and B, unless expressly defined otherwise in the individual case. “At least one of A and B” or “A and/or B” may be used as alternative wording for the same combinations. This applies equivalently to combinations of more than two elements.

If a singular form, for example “a, an” and “the”, is used, and the use of only a single element is neither explicitly nor implicitly defined as mandatory, other examples may also use multiple elements to implement the same function. When a function is described in the following as being implemented using multiple elements, further examples may implement the same function using a single element or a single processing entity. Furthermore, it will be understood that the terms “comprises”, “comprising”, “has” and/or “having” when used describe the presence of the indicated features, whole numbers, steps, operations, processes, elements, components and/or a group thereof, but do not thereby exclude the presence or the addition of one or more further features, whole numbers, steps, operations, processes, elements, components and/or a group thereof.

Magnetic sensors based on tunnel magnetoresistance (TMR) technology are often used in applications that require a sensitive measurement of magnetic fields with a low power consumption, such as in biometric sensors or IoT applications. The current state of the art typically uses TMR sensor bridges that are directly coupled to analogue processing circuits or analogue-to-digital converters. However, these arrangements have limitations, in particular in terms of a minimum achievable supply voltage and the energy consumption. This is due, among other things, to threshold voltages and saturation voltages of the MOS transistors in directly coupled input stages of the processing circuits. In addition, undesirable effects such as offset voltages, increased noise and additional power consumption arise in conventional solutions. This results in the need for an improved solution that further reduces the supply voltage, minimizes the power consumption, and at the same time enables more precise signal processing.

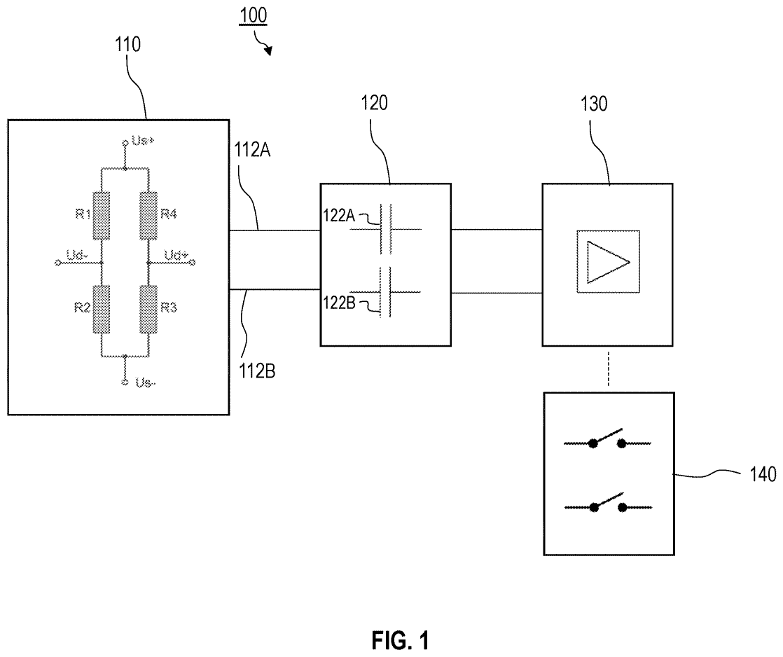

FIG. 1 schematically shows a block diagram of a circuit 100 for detecting a magnetic field according to the present disclosure.

The circuit 100 comprises an xMR sensor bridge 110 having a first and second output node 112A, 112B in order to provide a differential sensor signal based on an external magnetic field. An average value of voltages of the output nodes 112A, 112B to earth forms a first common operating point (common mode voltage).

The xMR sensor bridge 110 shown in FIG. 1 can be realized as a so-called Wheatstone bridge. A Wheatstone bridge is an electrical circuit arrangement consisting of four resistors connected to each other in a bridge circuit. In an xMR-based Wheatstone bridge, the resistors are at least partially magnetoresistive components whose resistance values change based on an externally applied magnetic field. These magnetoresistive resistors may be configured, for example, as anisotropic magnetoresistive (AMR), giant magnetoresistive (GMR) or preferably tunnel magnetoresistive (TMR) resistors. TMR resistors offer a particularly high sensitivity and enable a low energy consumption. The output nodes 112A and 112B of the Wheatstone bridge are typically each located between two opposite resistance branches of the bridge. This means that one output node (for example 112A) is tapped off between an upper and a lower resistor in one branch of the bridge, and the second output node (for example 112B) is tapped off correspondingly in the other branch between the two resistors arranged there. The so-called common mode voltage refers to the average voltage between these two output nodes 112A and 112B, measured against earth. This common mode voltage forms a common reference point around which the differential voltages of the two output nodes 112A, 112B change symmetrically when the magnetic field and thus the resistance values change.

The circuit 100 also comprises a coupling capacitor stage 120 which is coupled to the output nodes 112A, 112B of the xMR sensor bridge 110. The coupling capacitor stage 120 is used in the circuit 100 to transfer the differential sensor signal from the xMR sensor bridge 110 capacitively to a subsequent (analogue) processing circuit 130 and at the same time to decouple unwanted DC voltage components, such as the common mode voltage. It thus acts as a DC voltage blockade, thus making it possible reduce or eliminate interfering DC voltage levels or offset voltages. The coupling capacitor stage 120 comprises at least two capacitors 122A, 122B each connected to one of the output nodes 112A and 112B of the xMR sensor bridge 110. These capacitors 122A, 122B are connected in series between the output nodes 112A, 112B of the xMR sensor bridge 110 and inputs of a subsequent processing circuit 130. This arrangement enables the subsequent processing circuit 130 to process the differential sensor signal with high precision, since interfering influences of the DC voltage levels are significantly reduced.

The processing circuit 130 is connected via the coupling capacitor stage 120 to the xMR sensor bridge 110 and is configured to provide a second, different common operating point in order to achieve a function at a minimum supply voltage. The processing circuit 130 provides a second common operating point which is deliberately selected to be different from the original common mode voltage of the sensor bridge 110, specifically at a lower level, for example. This can be carried out by virtue of the processing circuit 130 forcing a defined reference voltage or a specific voltage level at the inputs of the processing circuit 130 via the coupling capacitor stage 120. Using suitable circuit measures, such as the use of resistance networks, switched capacitances or specific voltage references, the second operating point can be shifted downwards or upwards in a targeted manner. The deliberate change of this second operating point means in particular that the processing circuit 130 or the entire circuit 100 can be operated at a lower supply voltage. The background lies in the fact that the minimum required supply voltage is typically determined by a sum of certain critical voltage potentials, such as threshold or saturation voltages of transistors used in the processing circuit 130. Shifting the common operating point to a lower (or higher) voltage level makes it possible to reduce this total voltage, and thus it is possible to reliably operate the processing circuit 130 or the entire circuit 100 with a lower supply voltage. This directly results in a significantly improved energy efficiency and at the same time expands the possible uses of circuit 100, in particular in energy-limited applications.

The circuit 100 further comprises a clock unit 140 which is configured to operate the circuit 100 in at least two switching phases, wherein offset components of the processing circuit 130 are detected and stored in a first switching phase at the second operating point and a component derived from the sensor signal, based on the second common operating point, is amplified or compared in a second switching phase. In the first switching phase, also referred to as the “offset correction phase” or “auto-zero phase”, an internal offset of the processing circuit 130 is first determined. For this purpose, the processing circuit 130 is operated at its second common operating point (a defined reference level), but a sensor signal is not yet processed. In this phase, the processing circuit 130 captures only its own internal offset voltages, e.g., voltage deviations, that are not caused by the magnetic field to be measured. These determined offset values are then stored, for example in the capacitors 122A, 122B. In the subsequent second switching phase, the so-called “signal evaluation phase”, the actual processing of the sensor signal takes place. The differential sensor signal (whose DC component has been capacitively decoupled) coming from the xMR sensor bridge 100 is now supplied to the processing circuit 130. This sensor signal is now either amplified or compared with a defined reference voltage. The offset stored in the first phase is taken into account and effectively subtracted such that the result is an accurate, offset-free sensor signal. This two-phase mode of operation allows interfering offset voltages of the processing circuit 130 to be almost completely compensated for, which significantly increases the accuracy and sensitivity of the entire circuit.

The processing circuit 130 can be constructed differently depending on the specific implementation and can comprise a multiplicity of possible circuit elements. For example, it could include a comparator used to distinguish voltage signals, an amplifier for signal amplification, an analogue-to-digital converter (ADC) for digitizing the analogue sensor signal, or a voltage-controlled or current-controlled oscillator that converts the sensor signal into a frequency-dependent signal.

Specifically, the processing circuit 130 can be configured as a so-called auto-zero comparator which captures and stores internal offset voltages in a first operating phase using the capacitors integrated in the coupling capacitor stage 120. In the subsequent second operating phase, the offset-adjusted sensor signal is then compared. Alternatively, the processing circuit 130 may also be configured as an auto-zero amplifier which captures and stores its offset in a first phase in order to provide the sensor signal with an offset-corrected gain in a second phase.

In addition, the processing circuit 130 can operate according to a so-called correlated double sampling (CDS) method. In this method, two samples of the sensor signal are recorded in two different operating phases, firstly the original signal including the offset and then an inverted signal including the same offset. Forming the difference between these two samples results in an amplified and simultaneously offset-adjusted sensor signal.

Further, the processing circuit 130 may be coupled to an additional clock unit (not shown) which alternately activates and deactivates the xMR sensor bridge 110 and/or the processing circuit 130 in a so-called duty cycle mode in order to further reduce a power consumption.

The processing circuit 130 may include a resistance network and/or current sources connected in parallel in order to flexibly set the second common operating point. Alternatively, it would be possible to use a switched capacitance network (switched capacitor network) which generates defined voltages by switching capacitors and thus determines the exact position of the second operating point.

The processing circuit 130 may comprise a reference device which assigns a defined reference voltage to a coupling capacitor 122A, 122B in the first operating phase, which voltage differs specifically from the original common mode voltage of the xMR sensor bridge 110. This reference device could in particular consist of an electrical resistor which is connected on the one hand to the coupling capacitor 122A, 122B and to an output of the processing circuit 130 and on the other hand is coupled to earth in order to thus precisely produce the desired reference voltage level.

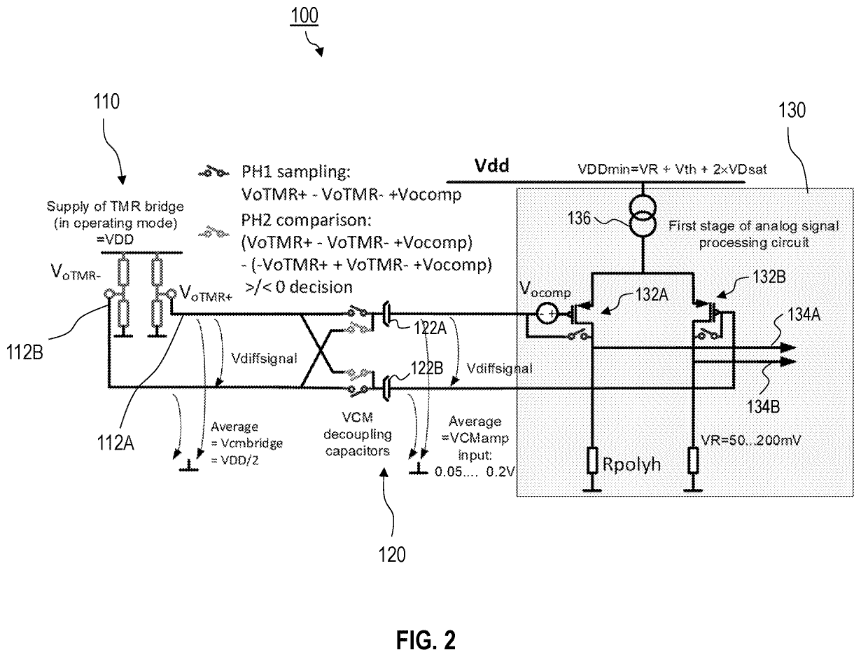

The example implementation of the circuit 100 shown in FIG. 2 essentially comprises the four functional blocks: TMR sensor bridge 110, coupling capacitor stage 120, processing circuit 130, and a plurality of switches that can be controlled by the clock unit 140 (not shown).

The TMR sensor bridge 110 is realized as a Wheatstone bridge with four TMR resistors and is supplied via a supply voltage VDD during operation. Two nodes on the bridge 110 serve as output nodes which are referred to as VoTMR+ (112A) and VoTMR− (112B). These two nodes 112A, 112B carry the differential sensor signal and are each connected via their own line to the coupling capacitor stage 120.

The coupling capacitor stage 120 comprises two coupling capacitors 122A, 122B, the first electrodes of which (on the left) are each connected to the output nodes 112A and 112B of the TMR sensor bridge 110. In a first switching phase PH1, the coupling capacitor 122A is connected to the output node 112A of the bridge 110 and the coupling capacitor 122B is connected to the output node 112B of the bridge 110. In a second switching phase PH2, the coupling capacitor 122A is connected to the output node 112B and the coupling capacitor 122B is connected to the output node 112A. The second electrodes (on the right) of capacitors 122A, 122B are each connected to differential inputs of the processing circuit 130.

Both inputs of the processing circuit 130 are each supplied to gate connections of two transistors 132A, 132B. The second electrode of the coupling capacitor 122A is coupled to the gate of transistor 132A. The second electrode of the coupling capacitor 122B is coupled to the gate of transistor 132B. The two transistors 132A, 132B can be configured as MOS transistors and together form a differential input stage. The source connections of both transistors 132A, 132B are connected together to a current source 136 which is fed by the supply voltage Vdd. The current source 136 provides a constant current which is divided between the two branches of the differential stage depending on the difference between the input voltages.

The drain connections of the two transistors 132A, 132B each lead to outputs 134A and 134B of the processing circuit 130. These two outputs 134A,134B carry out an amplified differential output signal out of the processing circuit 130. The outputs 134A and 134B are each connected to earth via (highly doped polysilicon) resistors Rpolyh. These resistors are used to generate a defined second common operating point via their voltage drop. The voltage range of this operating point can be approximately 50 to 200 mV, e.g., significantly below the usual common mode voltage of the TMR bridge (for instance VDD/2).

In the first switching phase PH1, the second electrode of coupling capacitor 122A is connected to the gate of transistor 132A and to the output 134A, and the second electrode of coupling capacitor 122B is connected to the gate of transistor 132B and to the output 134B. In the second switching phase PH2, the second electrode of coupling capacitor 122A is only connected to the gate of transistor 132A (not to the output 134A) and the second electrode of coupling capacitor 122B is only connected to the gate of transistor 132B (not to the output 134B).

In the first switching phase PH1, the first electrodes of the coupling capacitors 122A and 122B are thus connected to the respective output nodes 112A and 112B of the TMR sensor bridge, while at the same time their second electrodes are connected to the respective gates of the transistors 132A and 132B and to the outputs 134A and 134B of the processing circuit 130. In this configuration, the processing circuit 130 forms an auto-zeroing comparator. In this so-called auto-zero phase, a possible offset of the processing circuit 130 is captured via the coupling capacitors 122A, 122B. This offset can result, for example, from asymmetries within the transistors 132A,132B or from static interfering variables and leads to a systematic deviation of the comparison result. The offset is stored in this phase as a charge in the coupling capacitors 122A,122B.

In the second switching phase PH2, the first electrodes of the coupling capacitors 122A and 122B are connected to the respective other output nodes 112B and 112A of the TMR sensor bridge 110 and the connections of the second electrodes to the outputs 134A and 134B are interrupted, with the result that the second electrodes of the coupling capacitors 122A, 122B are now connected exclusively to the gates of the respective transistors 132A, 132B. In this phase, which is also referred as the comparison phase, the actual differential sensor signal is processed. The offset stored in the first phase is automatically compensated for, since the stored charge in the capacitors 122A, 122B generates a corresponding counter-voltage. The signal derived from the sensor signal is thus supplied to the differential amplifier stage after subtracting the stored offset. The resulting differential voltage is converted into a differential output signal that is available at the outputs 134A and 134B.

This two-phase mode of operation enables the circuit 100 to process even very small sensor signals with high accuracy at the same time, since interfering offset components are largely suppressed. At the same time, the low second common operating point, which is set via the resistors Rpolyh between the respective drain connections of the two transistors 132A, 132B and earth, enables a function of the circuit even at a very low supply voltage, which is particularly advantageous for power-saving applications.

In summary, FIG. 2 thus shows a circuit 100 in which the xMR sensor bridge 110 is configured as a Wheatstone bridge with four TMR resistors, the two output nodes 112A, 112B of which for providing a differential sensor signal are each connected via their own line to a coupling capacitor stage 120. The coupling capacitor stage 120 has at least two coupling capacitors 122A, 122B, the first electrodes of which are connected in a first switching phase PH1 to the respective output nodes 112A, 112B of the TMR sensor bridge 110 and in a second switching phase PH2 in the opposite direction to the respective other output nodes. The second electrodes (right-hand electrodes) of the coupling capacitors 122A, 122B are each coupled to gate connections of two transistors 132A, 132B of a differential input stage in the processing circuit 130. The transistors 132A, 132B have source connections that are jointly coupled to the supply voltage via a current source 136, and drain connections that each lead to outputs 134A, 134B which are connected to earth via resistors (Rpolyh). The circuit (100) is configured in the first switching phase (PH1) to capture and store an offset of the processing circuit 130 (auto-zero phase), while in the second switching phase (PH2) the differential sensor signal is processed further after subtracting the stored offset (comparison phase), with the result that the circuit 100 allows precise signal processing at a low supply voltage.

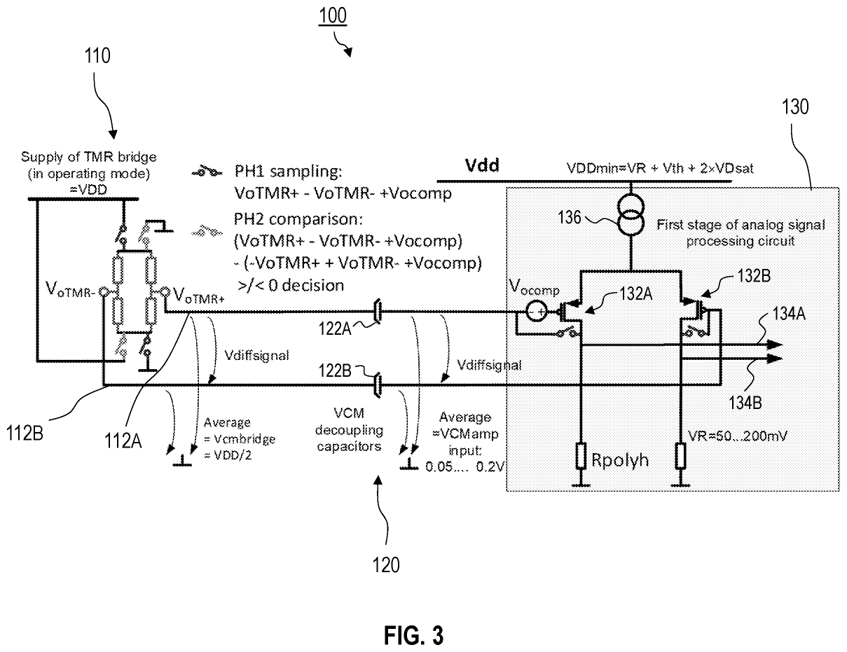

FIG. 3 shows a variant of the circuit 100 for detecting a magnetic field, which differs in some points from the implementation shown in FIG. 2. While the basic structure—comprising the TMR sensor bridge 110, coupling capacitor stage 120, and processing circuit 130—is preserved, there is a difference in the way signals are switched between the two switching phases PH1 and PH2.

In FIG. 2, the phase switching is carried out using connection switches between the output nodes 112A, 112B of the TMR bridge 110 and the coupling capacitors 122A, 122B. In the first phase (PH1), the coupling capacitors 122A and 122B are connected directly to the corresponding output nodes 112A and 112B. In the second phase (PH2), a cross-connection is carried out: the coupling capacitors 122A and 122B are connected to the opposite output nodes 112B and 112A in each case. This switching requires switches arranged in the signal path between the TMR bridge 110 and the analogue processing circuit 130.

In contrast, FIG. 3 shows an alternative implementation in which connection switches between the TMR bridge 110 and the coupling capacitors 122A, 122B are omitted. Instead, switches required for the phase switching are integrated into the TMR bridge 110 itself. The polarity of the output differential signal is not achieved by switching the connection assignment of the coupling capacitors 122A, 122B, but by internal switching within the bridge circuit 110. The coupling capacitors 122A and 122B always remain connected to the same output nodes, meaning that the signal routing between the TMR bridge 110 and the processing circuit 130 remains constant.

In the first switching phase PH1, the upper supply connection of the TMR bridge 110 is connected to the supply voltage VDD, while the lower supply connection of the TMR bridge 110 is connected to earth. As a result, the bridge current flows in the usual direction from VDD to earth, and the differential voltage signal generated at the output 112A, 112B of the bridge 110 corresponds to the normal polarization of the bridge circuit. In the second switching phase PH2, however, the polarity of the supply is reversed: The upper supply connection of the TMR bridge 110 is connected to earth, while the lower connection is connected to the supply voltage VDD. In this way, the direction of current flow through the bridge 110 is reversed, as a result of which the generated differential output signal is also inverted. This inversion is functionally equivalent to a cross-connection of the output signals, as is realized in other circuit variants according to FIG. 2, and makes it possible to carry out a correlated comparison for offset compensation, without the need for switching in the signal path between the bridge and the evaluation circuit.

An advantage of this design is that, by avoiding connection switches between the bridge 110 and the coupling capacitor stage 120, potential capacitive imbalances (mismatch) are eliminated, which could otherwise lead to a non-compensatable offset in the analogue processing circuit 130. Since the inputs of the processing circuit 130 are operated at constant nodes during both phases, the input capacitance of the evaluation circuit is identical across the two phases. This significantly improves the offset stability and repeat accuracy of the circuit, in particular for very small input signals.

Overall, FIG. 3 thus shows an alternative to the circuit shown in FIG. 2, in which the signal paths between the sensor and the evaluation are kept stable by integrating the switching logic into the TMR bridge 110. This cannot only simplify the circuit design, but can also improve the signal processing precision by reducing interfering capacitive effects.

In summary, FIG. 3 thus shows a circuit 100 in which the supply polarity of the xMR sensor bridge 110 is switched in two different switching phases (PH1, PH2), such that the upper supply connection in the first phase (PH1) is connected to a supply voltage (VDD) and the lower supply connection is connected to earth, but, in the second phase (PH2), the upper supply connection is connected to earth and the lower supply connection is connected to the supply voltage (VDD). As a result, the differential output signal from the xMR sensor bridge 110 is inverted within the bridge itself, rather than by external connection switches between the bridge outputs 112A, 112B and the coupling capacitor stage 120. The coupling capacitors 122A, 122B each remain connected to the same outputs 112A, 112B in both switching phases, and so capacitive imbalances in the signal path to the processing circuit 130 are reduced and an improved offset compensation can be achieved.

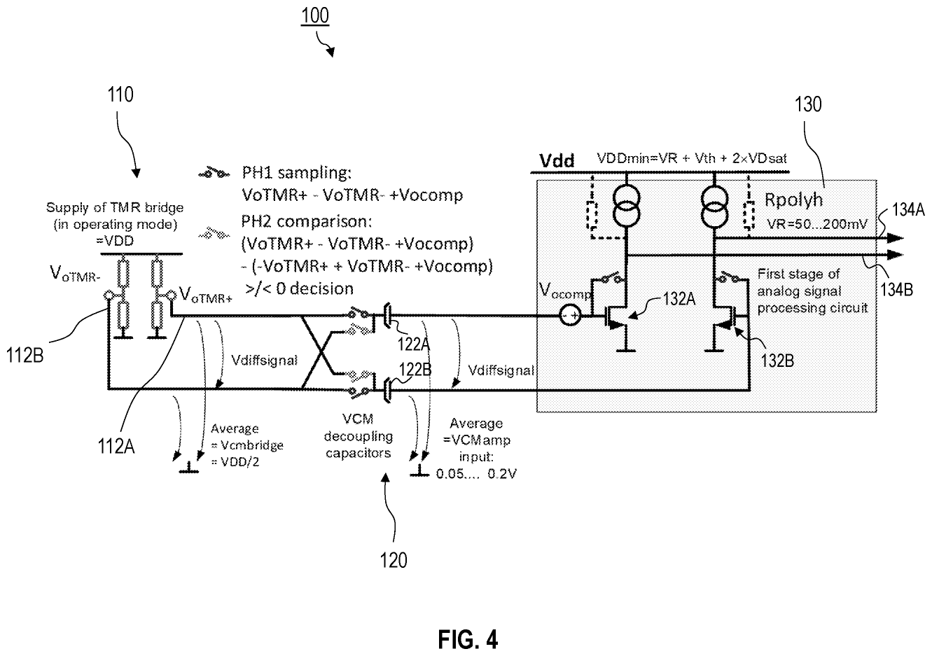

FIG. 4 shows a further variant of the circuit 100 for detecting a magnetic field, which differs from the implementation shown in FIG. 2. The basic architecture is also preserved here and comprises a TMR sensor bridge 110, a coupling capacitor stage 120, and a processing circuit 130. Differences lie in particular in the design and method of operation of the processing circuit 130.

In FIG. 2 and FIG. 3, the processing circuit 130 is realized as an auto-zeroing comparator with a differential input stage consisting of two transistors 132A, 132B, wherein the second common operating point—e.g., the common mode voltage at the outputs 134A, 134B—is defined by resistors Rpolyh to earth. As a result, the operating point is typically at a low voltage level, in the range of 50 to 200 mV, which enables a stable function at a low supply voltage.

In FIG. 4, on the other hand, a different approach is followed: In this case, the output nodes 134A, 134B of the differential processing circuit 130 are not interconnected via resistors to earth, but are each connected to controlled current sources which in turn are connected to the supply potential Vdd. In FIG. 4, the two transistors 132A and 132B are in a common source configuration. Their gate connections receive the differential input signal from the coupling capacitors 122A, 122B, while their source connections are connected to earth. The drain connections of the transistors 132A,132B form the output nodes 134A and 134B of the circuit.

A current source branch is respectively connected between each of the drain connections and the supply voltage Vdd and can consist of two components: a respective current source and a resistor Rpolyh optionally connected in parallel. The current source actively controls current, while the resistor Rpolyh causes a passive voltage drop. Both elements are connected in parallel between Vdd and the respective drain connection of the transistors 132A and 132B. Thus, from the drain connection of the transistor 132A, a branch leads simultaneously to a current source and a resistor Rpolyh, the other ends of which are both at Vdd. The same applies to the drain connection of the transistor 132B. The drain connections of these transistors simultaneously form the outputs of the circuit (134A and 134B).

This interconnection results in a difference compared to the variant in FIG. 2: The common mode voltage at the outputs 134A and 134B is deliberately shifted upwards, e.g., closer to Vdd. Whereas in FIG. 2 the second common operating point is typically in the range of 50 to 200 mV by virtue of discharge via resistors to earth, it can be in a significantly higher range in FIG. 4, depending on the current level and the resistance values.

This configuration allows the circuit to be operated with a further reduced supply voltage. The background is that the common source structure only requires a voltage drop of approximately Vth+Vdsat between Vdd and the signal level at the outputs—in comparison with the conventional differential amplifier stage in FIG. 2 which has to factor in at least two saturation voltages (2×Vdsat). The required voltage gap between the operating points is thus reduced, which directly leads to a reduction in the minimum operating voltage VDDmin.

In summary, FIG. 4 thus shows a circuit 100 in which the processing circuit 130 comprises two transistors 132A, 132B in a common source configuration, the source connections of which are connected to earth, while their drain connections form the outputs 134A, 134B of the circuit 100. A current source branch is respectively arranged between each source connection and the supply voltage (Vdd) and consists of an actively current-controlling current source and a resistor (Rpolyh) optionally connected in parallel. As a result, the common mode voltage at the outputs 134A, 134B can be deliberately raised compared to a first operating point present at the xMR sensor bridge 110 and the operation of the entire circuit 100 can be made possible with a further reduced supply voltage (VDDmin).

FIG. 4 thus shows an implementation of the processing circuit 130 in which voltage-optimized operation can be achieved by the combination of a common source configuration, current-controlled operation and a targeted common mode increase. The parallel arrangement of current sources and optional resistors between the drain nodes of the transistors 132A, 132B and VDD allows precise setting of the output operating point and highly accurate, energy-efficient evaluation of the magnetic input signal.

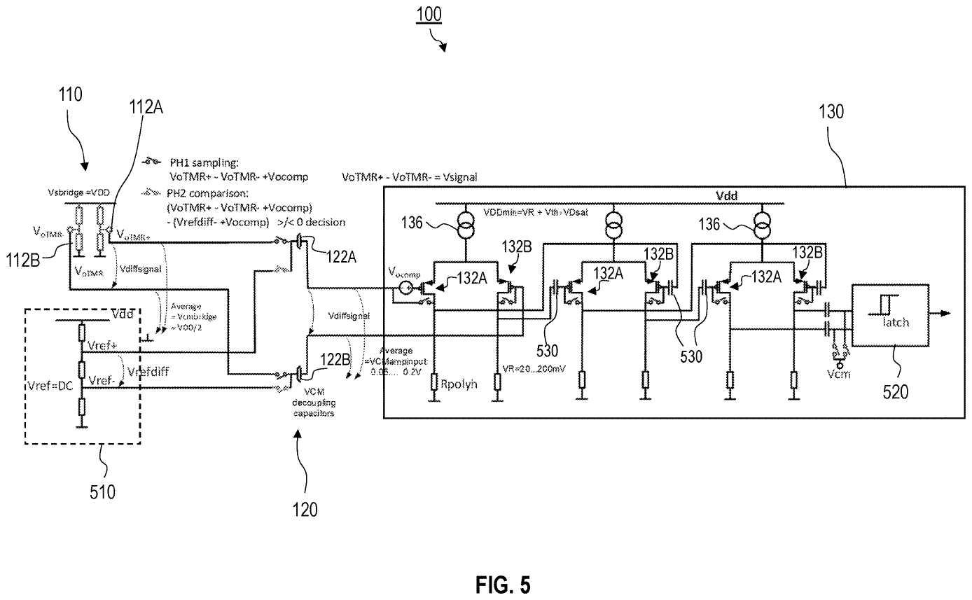

FIG. 5 shows a further implementation of the circuit 100 which differs in a plurality of points from the variant shown in FIG. 2. Here, too, the basic structure with a TMR sensor bridge 110, a coupling capacitor stage 120 and a processing circuit 130 is preserved, but the method of operation of the coupling capacitors 122A, 122B and the offset compensation method are changed. In addition, the processing circuit 130 in FIG. 5 is more complex and comprises a plurality of differential amplifier stages connected in series and a final latch.

A difference to FIG. 2 is the procedure with the coupling capacitors 122A, 122B in the second switching phase PH2. Whereas in FIG. 2 both phases PH1/PH2 mainly carry out switching between the sensor output nodes 112A, 112B, in FIG. 5 in the second phase PH2 use is made instead of an additional reference voltage branch 510, the voltages of which Vref+, Vref−, and Vrefdiff (Vref+−Vref−) can be seen at the bottom left of FIG. 5. As a result, the sensor signal sampled in the first phase PH1 (with an offset) is not simply compared with an inverted sensor signal or a directly switched sensor output in the second phase PH2, but against a defined reference voltage.

This procedure does not correspond to a Correlated Double Sampling (CDS) method in which the sensor signal is recorded in the phase PH1 and is measured against a reference variable in the second phase PH2. Since the same processing circuit 130 is used in both phases, interference and offset components that change slowly or are constant can be almost completely eliminated. Unlike in the classic auto-zero method in which the offset is compensated for in a separate measurement, switched capacitor compares the same circuit configuration against two different input conditions (sensor vs. reference). The difference between these two sampled values ultimately results in the usable sensor signal, largely without offset components.

In addition, it can be seen that the processing circuit 130 in FIG. 5 contains a plurality of amplifier stages from FIG. 2. Each of these stages includes a pair of transistors (132A and 132B), a current source 136 between the source connections of the transistors and VDD, and output resistors (or optionally current sources) between the drain connections and earth. Capacitances 530 between the outputs of the first amplifier stage and the inputs of the second amplifier stage serve to decouple DC voltage components (in particular an already existing or newly created offset) from one amplifier stage to the next. This prevents a DC offset occurring in the first amplifier stage from influencing the subsequent amplifier stage or even being amplified. At the same time, these coupling capacitors 530 enable the signal to be re-centred around a desired operating point or, in a further switching phase, enable the offset of the second stage to be captured and compensated for separately. This multi-stage decoupling and offset correction makes it possible to increase the accuracy of the entire signal processing, which is particularly important for very low supply voltages and small sensor signals. This cascade of differential amplifiers allows the signal spectrum to first be amplified and stabilized before being converted into a digital output signal in the final latch 520. This multi-stage amplification differs from the single-stage amplifier or comparator in FIG. 2, where only a single differential transistor stage is shown.

In summary, FIG. 5 thus shows a circuit 100 in which the processing circuit 130 comprises a plurality of differential amplifier stages connected in series and each with a current source 136. Capacitances 530 are arranged between the outputs of a previous differential amplifier stage in each case and the inputs of a subsequent differential amplifier stage in order to decouple DC voltage components including an offset from one stage to the next. A sensor signal together with an offset is captured in a first switching phase (PH1) and is compared with a reference voltage (Vref+, Vref−, Vrefdiff) in a second switching phase (PH2), with the result that a difference is formed. As a result, at a low supply voltage, multi-stage, offset-adjusted signal amplification can be achieved before a digital output signal is provided in a final latch 520.

FIG. 5 thus shows more complex signal processing than FIG. 2, by evaluating the TMR sensor via capacitive decoupling on the one hand and the targeted comparison with a reference voltage on the other hand. This architecture is particularly advantageous when extremely small sensor signals are intended to be captured precisely at a low supply voltage.

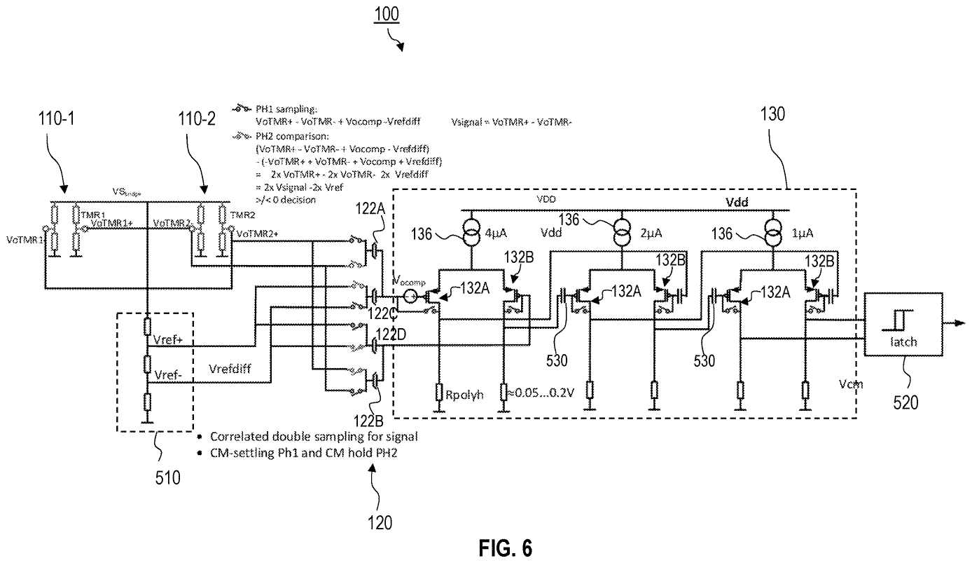

FIG. 6 shows a further implementation of the circuit 100 which is based on the concept of the architecture shown in FIG. 5, but further develops this using a Correlated Double Sampling technique (CDS). The main functional blocks—comprising the TMR sensor bridge 110, the coupling capacitor stage 120 and the processing circuit 130—are also present here. In comparison with FIG. 5, however, the architecture has been further optimized with regard to the signal routing, the signal quality and the processing depth.

A difference to FIG. 5 is the configuration of the TMR sensor bridge 110. Whereas in FIG. 5 use is made of a single bridge which generates a differential output signal, FIG. 6 shows two TMR bridges 110-1, 110-2 (TMR1, TMR2) which each provide a separate output signal. These bridges 110-1, 110-2 are interconnected for a differential magnetic field measurement: The output signal from the first bridge is referred to as VoTMR1+ and VoTMR1−, and the output signal from the second bridge is referred to as VoTMR2+ and VoTMR2−. This differential dual sensor structure allows an external magnetic field to be measured differentially.

In the first switching phase PH1, the sensor signal (e.g., VoTMR2+−VoTMR1−) is stored on the coupling capacitor 122A together with an internal offset of the subsequent circuit 130. At the same time, the other sensor signal (VoTMR1+−VoTMR2−) is stored on the coupling capacitor 122B, and Vref−and Vref+are also stored on the coupling capacitors 122C and 122D. In the second switching phase PH2, these assignments are reversed, with the result that the previously unused sensor signal and the respective other reference voltage are now applied to the relevant capacitor. This cyclic procedure corresponds to Correlated Double Sampling (CDS) in which the same processing circuit 130 is operated in two correlated but different input states (sensor signal plus offset vs. inverted or reference-based signal). The difference between these two states largely compensates for the offset and also reduces low-frequency interfering components such as 1/f noise.

A further difference to FIG. 5 is the configuration of the processing circuit 130. As already shown in FIG. 5, a plurality of differential amplifier stages connected in series are also present in FIG. 6. In FIG. 6, however, it can also be seen that these stages are operated with differently dimensioned current sources 136: The first stage is fed with a current of 4 μA, the second with 2 μA and the third with only 1 μA. This decreasing current scaling across the stages allows for tiered, low-distortion signal amplification while minimizing the power consumption at the same time. In this way, the sensor signal can first be amplified and stabilized before it is converted into a digital output signal in a final latch 520.

Unlike in the pure auto-zero method which only provides for offset measurement and compensation within one switching phase, in the CDS method used here the sensor signal is sampled in both phases PH1/PH2, but once with the respective reference voltages and once with the actual magnetic input signal. This increases the signal capture accuracy, since low-frequency interference or system-related offsets are effectively suppressed by the correlated formation of a difference.

In summary, FIG. 6 thus shows a circuit 100 having at least two TMR bridges 110-1, 110-2 which each provide separate sensor output signals (VoTMR1+, VoTMR1−, VoTMR2+, VoTMR2−). The coupling capacitor stage 120 is configured to capture a combination of these sensor output signals together with associated offset components in the first switching phase (PH1) and to compare this combination against a reference voltage (Vref+, Vref−, Vrefdiff) in the second switching phase (PH2) (Correlated Double Sampling). The processing circuit 130 comprises a multi-stage, series-connected differential amplifier arrangement (132A, 132B, 136) with tiered currents (e.g., 4 μA, 2 μA and 1 μA) for the current-optimized amplification of the sampled sensor signals. This creates a differential dual sensor structure that enables improved noise suppression and high-precision and energy-efficient signal processing at a very low supply voltage.

FIG. 6 thus shows differential TMR evaluation with a double bridge structure, correlated double signal sampling and multi-tiered, current-optimized amplification. In comparison with FIG. 5, this architecture can provide further improved noise suppression, a higher signal purity and increased energy efficiency, in particular for very small magnetic input signals at an extremely low supply voltage.

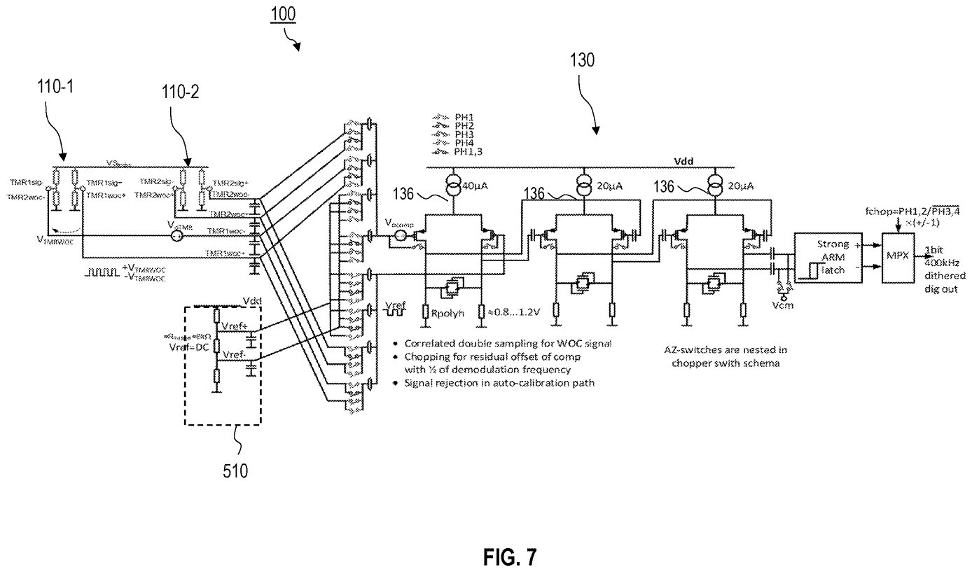

The circuit 100 shown in FIG. 7 further extends the principle of two-phase correlated double sampling (CDS) presented in FIG. 6 by superimposing an additional chopper technique. While the basic structure—comprising the TMR sensor bridge 110, coupling capacitor stage 120 and multi-stage analogue processing circuit 130—is largely preserved compared to FIG. 6, the implementation shown here extends the number of effective switching phases from two to four.

In FIG. 6, the two phases PH1 and PH2 are mainly used on the one hand to transfer the sensor signal with an offset to the coupling capacitors 122 of the coupling capacitor stage 120 and to create an inverted or reference-based signal on the other hand, which leads to the compensation of offset and low-frequency interference. In the implementation presented in FIG. 7, this basic principle is superimposed with an additional chopper technique. Chopper switches are typically used to further minimize the remaining offset and unwanted distortions of the subsequent amplifier stages. The chopper technique operates at a higher clock frequency which is superimposed on the actual CDS frequency scheme.

Based on the switching phases PH1, PH2, PH3, PH4, it can be seen that there are more than two correlated measurement and comparison phases here. One portion of the switches implements the two-phase CDS (PH1/PH2), while a further portion cyclically “chops” the signal and/or the reference voltage in order to average residual offsets of the amplifier stages. This nested procedure is illustrated by the fact that some switches labelled “PH1,3” and “PH2,4” overlap.

In the original phases PH1 and PH2—similar to FIG. 6—the sensor signal and the reference voltages are switched to the capacitors in a time-shifted manner in order to compensate for offset components using a classic correlated double sampling method (CDS). In addition, however, a higher clock frequency operates and is “grafted” onto these two basic phases and inverts either the signal or the reference in the chopper phases (PH3, PH4).

This nesting causes further switches to be switched within each sampling cycle (which is still defined by PH1/PH2) in order to further reduce the remaining comparator offset and low-frequency noise (for example 1/f noise). In FIG. 7, this is visible, among other things, from the fact that the auto-zero switches (“AZ switches”) and the chopper switches intermesh (“nested in chopper switch schema”). Each signal path (or reference path) is thus sampled several times per complete cycle in a slightly different constellation, which results in a statistical or systematic eradication of remaining offset and noise components.

The multi-stage amplifier chain (with tiered currents of 40 μA, 20 μA and 20 μA) is similar to FIG. 6 and amplifies the alternately inverted or reference-related signals. A Strong-ARM latch (including a multiplexer) then digitizes the end result which is particularly low in offset and noise due to the combination of CDS and chopping. This nested four-phase operation is particularly suitable for precise measurements with a very low energy budget, since the complex correction steps (auto-zero, CDS and chopping) are always only briefly clocked and do not cause any appreciable quiescent current over the rest of the operating cycle.

In summary, FIG. 7 thus shows a circuit 100 in which the processing circuit 130, in addition to a two-phase correlated double sampling method (CDS) with the switching phases (PH1, PH2), additionally has a superimposed chopper technique with further switching phases (PH3, PH4), with the result that both the sensor signal and a reference voltage are sampled several times in a different polarity in each sampling cycle. Some of the switches are integrated into the chopper switches (“nested in chopper switch scheme”) for offset compensation (auto-zero switches). The multi-stage differential amplifier circuit with tiered currents (e.g., 40 μA, 20 μA, 20 μA) amplifies the signal inverted or reference-related by the chopper and CDS technique.

This circuit differs from that in FIG. 6 above all by the additional chopper method which goes beyond the existing CDS phases and introduces a plurality of further switching phases. This further reduces the already very low offset and further reduces the noise, which is advantageous in particular for high-precision measurements at a low operating voltage and with a low energy budget.

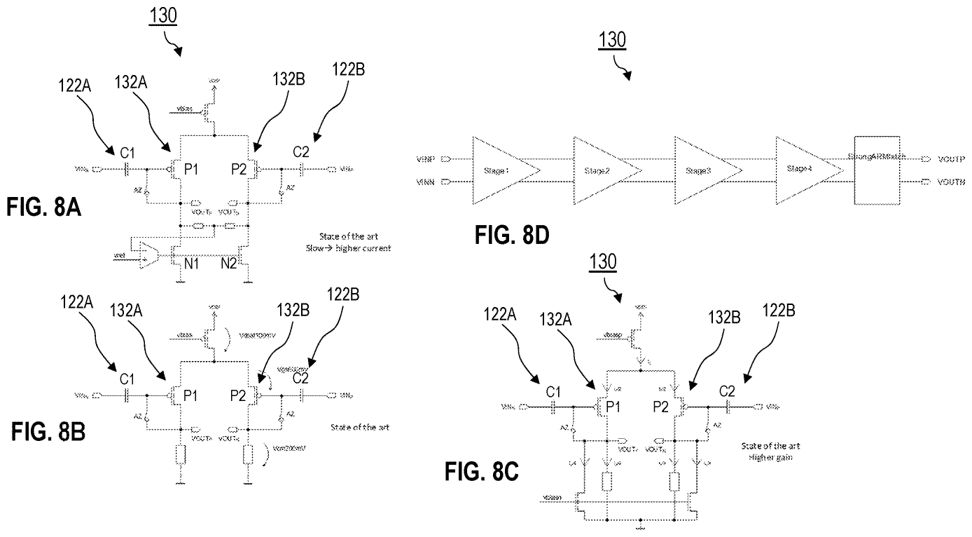

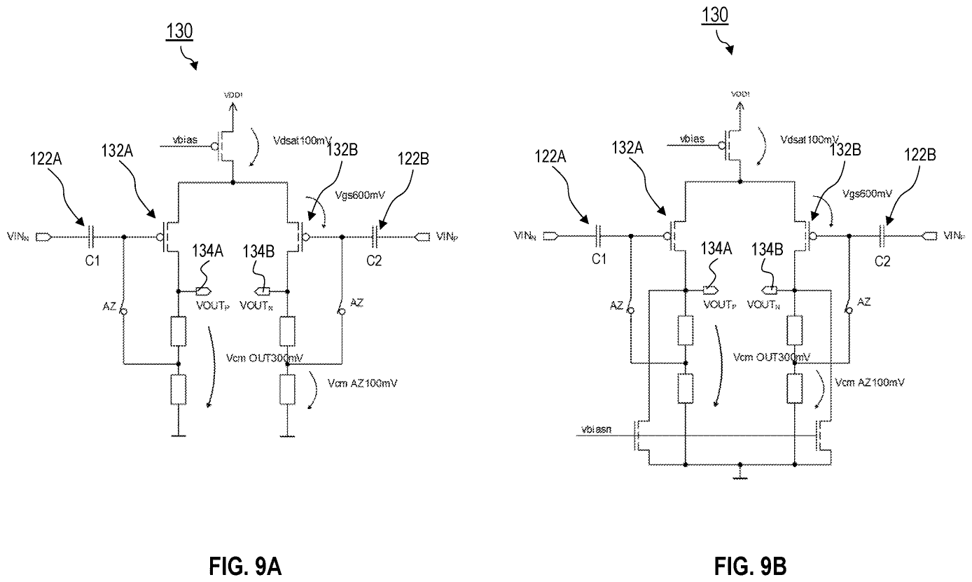

A few possible circuit modules for the processing circuit 130 are described below with reference to FIGS. 8 and 9.

FIG. 8A shows an integrated auto-zero comparator with a general input configuration.

A differential input is effected via the nodes VINp and VINn. These can each be connected to the coupling capacitors C1 and C2 which in turn control the gates of the two input PMOS transistors P1 and P2. In the auto-zero phase (when the AZ switch is closed), not only are the gates of the input transistors connected to the coupling capacitors C1 and C2, but the gates are also simultaneously connected to the outputs (VOUTp, VOUTn). This simultaneous connection produces a “short circuit” between the inputs and the outputs, with the result that the comparator virtually calibrates itself to zero during this phase. The principle behind this is that, during the auto-zero phase, the transistors ensure on the one hand that no differential signal is present at the outputs (since both the inputs and the outputs have an identical potential) and on the other hand that the offset voltages of the comparator that occur are stored as a charge quantity in the coupling capacitors. As soon as the auto-zero switches are subsequently opened and the comparison switches are closed, this stored charge quantity is retained as an “offset counter-voltage”, while the actual sensor signal is now present. This results in an effective subtraction of the previously stored offset in the comparison phase, which results in a considerably more accurate comparison result.

An additional aspect of this circuit is the handling of the common mode voltage on the output side. The two NMOS transistors N1 and N2 form, with the load resistors and current mirrors, an active differential amplifier stage, the outputs of which are VOUTp and VOUTn. These outputs are connected via high-value resistors RCM1 and RCM2 to an operational amplifier that monitors the average output voltage. The output of this operational amplifier controls the gate connection of the upper current source transistor, which is labelled Vbias. The aim of this control is to stabilize the common mode voltage at the output to a fixed reference value Vref.

Feedback via the high-value resistors is necessary because it captures the average voltage at the two outputs and controls it via the OTA (Operational Transconductance Amplifier). This stabilization is advantageous for the balanced operation of the comparator. Since the output common mode voltage is controlled via a closed control loop, the time constant of this control loop—in particular with high resistance values and small correction currents—can limit the total switching time of the circuit.

The processing circuit 130 shown in FIG. 8B corresponds in its basic structure to the previously described auto-zero comparator architecture, but differs in a significant point with regard to the implementation of the output stage design. Whereas the circuit in FIG. 8A uses a controlled common mode output with feedback via high-value resistors and an OTA (operational amplifier), in this variant the output common mode voltage is defined solely by passive resistors Rₗ_{₁} and Rₗ_{₂} to earth. The amplifier circuit is also constructed as a differential amplifier with PMOS input transistors P1 and P2, the sources of which are connected to the supply voltage VDD via a current source. The gates of the transistors are fed via coupling capacitors C1 and C2 which are switched accordingly in the two operating phases (auto-zero and comparison). The switching is carried out via switches that are connected to a common mode voltage (VCM) in the auto-zero phase and allow the sensor signal VINₚ/VINₙ to pass through in the comparison phase.

Unlike the previous architecture, no explicit control of the common mode output voltage is used here. Instead, the output common mode VCMₒᵤₜ is set purely passively by the resistors Rₗ_{₁} and Rₗ_{₂}. The resulting operating point at the outputs VOUTₚ and VOUTₙ is the voltage across these resistors as a function of the current through the transistors. In the configuration shown, this results in a typical output common mode voltage of approximately 200 mV. The voltage requirement of the circuit can be estimated using the depicted minimum values in typical 350 nm technology: The saturation voltage Vdsat of the current mirror transistor is approximately 100 mV, the gate source voltage Vgs of the PMOS input transistors is approximately 800 mV, and the output common mode VCMₒᵤₜ is 200 mV. This results in a minimum operating voltage VDD of approximately 1.1 V, below which the circuit would no longer operate correctly.

One aspect of this architecture is the effect of the choice of load resistors on the functionality. Higher resistance values Rₗ_{₁} and Rₗ_{₂} lead to a higher gain, but also to an increase in the output voltage and thus to a higher required supply voltage. Lower resistance values reduce the gain and therefore the signal swing, which in turn would have to be compensated for by downstream amplifier stages or a larger number of comparator stages, but this is associated with a higher power consumption. The circuit in this form is thus a compromise between supply requirement, amplification and energy efficiency.

Compared to the circuit in FIG. 8A with common mode control via an OTA, this design is simpler, requires fewer additional circuit parts and reduces the quiescent current of the common mode control. The disadvantage is a potentially lower stability of the output common mode voltage in the event of load changes and the limited control over its exact value. However, the fixed dimensioning of the resistors allows precise, technology-dependent setting of the operating point and offers a robust solution with low requirements for the dynamic response of the output common mode.

The processing circuit 130 shown in FIG. 8C shows a variant of the auto-zero comparator in which the output stage has been specifically modified such that the minimum required supply voltage can be reduced without having to resort to a controlled output common mode control loop. In contrast to the previous circuit in which the load resistors RL1 and RL2 alone generated the voltage drop to earth, an additional current path is introduced here that reduces the current flow through these resistors.

Specifically, uncontrolled current sources N1 and N2 are connected in parallel with each of the resistors RL1 and RL2, the sources of which are connected to earth and the gates of which are controlled by a common control voltage vbiasn. These current sources N1 and N2 derive a defined portion of the total current flowing from the input transistors P1 and P2. The remaining current continues to flow through the resistors RL1 and RL2, thus maintaining the voltage at the outputs VOUTP and VOUTN. The distribution of the current causes only part of the total current intensity to result in a voltage drop across the resistors. This results in a reduction in the output common mode voltage, since this results directly from the voltage drop across RL1 and RL2.

Reducing the common-mode output voltage also makes it possible to reduce the necessary supply voltage VDD, since the output nodes may be closer to earth. In a conventional topology, the supply voltage would have to be at least as high as the sum of the gate-source voltage of the input transistor, the saturation voltage of the current source, and the output voltage. By reducing the output voltage, VDD can also be reduced. At the same time, the resistance value of RL1 and RL2 remains high, thus maintaining the gain of the circuit.

In contrast to the circuit in FIG. 8B in which the entire current flows through the load resistors and thus a minimum voltage of approximately 1.1 V is required, this configuration allows a further reduction of the supply voltage without affecting the amplifier properties. The omission of complex control of the output common mode voltage using an OTA also reduces the complexity and the power consumption of the circuit. The offset, which can be caused by this asymmetric current distribution, is automatically recorded and compensated for in the downstream comparator stage by the sampling capacitors present there, with the result that it does not have a negative effect on the measurement accuracy.

Overall, the circuit shown represents a solution for reducing the operating voltage and thus the power loss while maintaining the signal gain, without having to resort to active common mode control. This concept is thus particularly suitable for energy-efficient, battery-powered applications with high accuracy requirements for a limited voltage budget.

FIG. 8D shows a schematic representation of a multi-stage, differential amplifier circuit with a downstream Strong-ARM latch. The input signals VINP and VINN are first supplied to a first amplifier stage (Stage 1) and are then each further amplified in three further amplifier stages (Stage 2 to Stage 4). The four amplifier stages form a cascade of preamplifiers that gradually amplify the differential input signal such that it is sufficiently large at the output to be reliably digitally evaluated.

A so-called Strong-ARM latch is connected to the end of the amplifier chain and acts as a fast, dynamic comparison and decision-making stage. It evaluates the amplified differential signal and provides the digital output signals VOUTP and VOUTN. This structure is suitable for power-saving, high-resolution comparators in applications with very small input signals and ensures that both precise preamplification and fast digital decision-making are possible.

A Strong-ARM latch is a special dynamic comparator which is used in CMOS circuits and is particularly suitable for applications with a low power consumption and high speed. This circuit combines the functions of a differential amplifier, a comparator and a latch in a single architecture. It is distinguished by the fact that it does not consume any static current in the idle state. Current only flows during the switching phase, e.g., at the moment at which a comparison decision is made.

The Strong-ARM latch can be operated in two temporally separated phases controlled by a clock signal. In the so-called precharge phase, when the clock level is low, the output nodes of the circuit are precharged to a defined voltage level—usually to the supply voltage. In the subsequent evaluation phase, when the clock signal increases, the differential input signal becomes effective. A small voltage difference between the two inputs is sufficient to cause rapid amplification of the differential signal through the regenerative feedback within the circuit. This results in one of the two outputs being discharged significantly faster than the other, and so the output signal clearly develops into one of two possible digital states due to positive feedback. This results in a robust, digital decision between the two input signals.

The regeneratively operating structure of the Strong-ARM latch ensures a high speed and a clear distinguishability of the output signals even with very small input differences. Since this architecture does not require a constant current flow, it is particularly energy-efficient and is extremely suitable for applications with temporally clocked signal processing, such as in analogue inputs of analogue-to-digital converters or in sensor interfaces. Due to its properties, the Strong-ARM latch is often used in highly integrated mixed signal systems that require high precision, low power consumption and fast switching operations.

The processing circuit 130 shown in FIG. 9A is a further development of the auto-zero comparator shown in FIG. 8B, in which in particular the load resistors are divided into two partial resistors each. This division forms a voltage divider, the tapping point of which defines the operating point for the input PMOS transistors during the auto-zero phase. In comparison with the circuit from FIG. 8B, where each output has only a single resistor to earth, the supply voltage can be further reduced by this without reducing the overall gain.

Although both circuits are similar in their general design, consisting of the transistors 132A and 132B, a common current source of VDD and coupling capacitors 122A, 122B for the auto-zero method, the splitting of the resistors has a significant effect: The node between the partial resistors is at a lower voltage level than is the case in FIG. 8B. The node between the partial resistors is connected to the second electrode of the respective coupling capacitor via the AZ switch. Whereas in the variant in FIG. 8B only a single resistance path per output node exists and thus a higher output common mode occurs, in FIG. 9A the output signal is further discharged to earth via a second partial path. As a result, the voltage difference between the gate and source (Vgs) of the input transistors can be kept lower, which directly leads to a lower minimum required supply voltage.

According to FIG. 9A, the processing circuit 130 may thus be configured such that each of its two outputs 134A, 134B is connected to earth via two series-connected partial resistors, thus resulting in a voltage divider. In an auto-zero phase, a node located between the partial resistors is coupled to the gate of an input PMOS transistor (132A, 132B) via an auto-zero switch (AZ switch).

As a result, the minimum operating voltage drops from approximately 1.1 V to approximately 950 mV, although the combined resistance values (sum of the two partial resistors per output) remain high and thus provide a high gain. An undesirable but accepted side effect is an additional offset at the outputs which is proportional to the ratio of the two partial resistors. However, this offset can be detected and compensated for in a subsequent comparator stage by the sampling capacitors present there, and so the measurement accuracy is not impaired. In contrast to the circuit according to FIG. 8B in which each output stage has only one resistor and accordingly requires a higher operating point, FIG. 9A thus allows a significantly reduced supply voltage requirement without the need for a complex common mode control loop.

The processing circuit 130 shown in FIG. 9B directly links to the principle presented in FIG. 9A, but adds further current sources in parallel with the load resistors in order to further increase the gain of the comparator without raising the minimum supply voltage. As before, the two input PMOS transistors 132A and 132B are connected to VDD via a current source and are switched in two operating phases (auto-zero and comparison) so that their offset is compensated for. The outputs 134A, 134B (VOUTP and VOUTN) are still connected to earth via load-forming resistors, in which case the operating point is raised to approximately 100 mV in the auto-zero phase and to approximately 300 mV during operation.

In contrast to the variant from FIG. 9A, however, additional, uncontrolled current sources are found in FIG. 9B in parallel with the load resistors between VOUTP and earth or VOUTN and earth. These ensure that part of the current that would normally flow through the resistors is branched off laterally. In this way, the total current intensity in the transistors 132A and 132B can be kept high, which results in a higher gain without significantly increasing the required voltage budget. Since the output common mode voltage remains stabilized at a low level due to the interaction of resistors and parallel current sources, the comparator can continue to operate with a supply voltage of well below 1 V. At the same time, the system is able to provide a sufficiently large gain, even during fast signal changes, which is particularly advantageous in duty-cycled operation. The circuit thus combines the supply voltage that is kept low from FIG. 9A with an even higher signal gain, without having to implement a complex common mode control loop.

According to FIG. 9B, the processing circuit 130 can thus have additional current sources in parallel with the load resistors between each output 134A, 134B and earth, with the result that part of the current flowing into the input transistors 132A, 132B is discharged laterally via these current sources in order to achieve a higher gain with an unchanged low output common mode voltage and to enable a supply voltage of well below 1 V without the need for a complex common mode control loop

The example implementations of the processing circuit 130 described with reference to FIGS. 8 and 9, including the variants with a controlled or uncontrolled output common mode and with an additional current path or voltage divider architecture, may be used in each case in example implementations of the present disclosure. Depending on the requirements for supply voltage, gain, offset compensation and energy efficiency, these circuit concepts can be flexibly integrated into the overall system and enable precise, power-saving signal processing, in particular in combination with capacitively decoupled xMR sensor bridges.

The example implementations described herein show various possibilities for the precise and energy-efficient evaluation of magnetic fields using xMR sensor bridges and downstream analogue processing circuits. The concepts presented include, inter alia, auto-zero comparators, source-follower structures, multi-stage differential amplifier chains, correlated double sampling (CDS) and superimposed chopper techniques. These approaches enable effective compensation of offset voltages, reliable processing of even very small sensor signals and operation at a particularly low supply voltage.

Depending on the application context, a balanced combination of high sensitivity, low power loss and structural simplicity is achieved by specifically adjusting the operating point, by using current-optimized amplifier stages or by integrating additional circuit elements—such as voltage dividers or parallel current sources.

The respective features of the individual example implementations are not limited to the isolated implementation in a particular circuit block, but can also be combined with each other. For example, it is possible to combine a processing circuit with a voltage divider and parallel current sources using a TMR bridge according to FIG. 3 or CDS logic according to FIG. 6. The use of a chopper technique according to FIG. 7 can also be combined with other optimization measures for reducing the operating voltage or for improving the noise suppression.

Overall, the disclosed concepts allow great freedom of design and flexibility in the implementation of high-precision, power-saving sensor systems which are suitable in particular for battery-powered, integrated or miniaturized applications with a strict energy and accuracy budget.

The aspects and features described in connection with a particular one of the previous examples may also be combined with one or more of the other examples to replace an identical or similar feature of this other example or to introduce the feature additionally into the other example.

Furthermore, it goes without saying that the disclosure of multiple steps, processes, operations or functions disclosed in the description or claims should not be interpreted as necessarily being in the described order, unless this is explicitly stated in the individual case or is mandatory for technical reasons. Therefore, the previous description does not restrict the execution of multiple steps or functions to a specific order. Furthermore, in other examples, a single step, a single function, a single process or a single operation may include and/or be broken into multiple substeps, subfunctions, subprocesses or suboperations.

If some aspects have been described in the preceding sections in connection with an apparatus or a system, these aspects are also to be understood as a description of the corresponding method. In this case, for example, a block, an apparatus or a functional aspect of the apparatus or the system may correspond to a feature, such as a method step, of the corresponding method. Correspondingly, aspects described in connection with a method should also be understood as a description of a corresponding block, a corresponding element, a property or a functional feature of a corresponding apparatus or of a corresponding system.

The following claims are hereby incorporated into the detailed description, each claim being able to stand alone as a separate example. It should also be noted that—although a dependent claim in the claims refers to a particular combination with one or more other claims—other examples may also comprise a combination of the dependent claim with the subject matter of any other dependent or independent claim. Such combinations are hereby explicitly proposed, unless it is stated in the individual case that a particular combination is not intended. Furthermore, features of a claim should also be included for any other independent claim, even if that claim is not directly defined as dependent on that other independent claim.

### ASPECTS

The following provides an overview of some Aspects of the present disclosure:
Aspect 1: A circuit for detecting a magnetic field, comprising: a magnetoresistive sensor (xMR) sensor bridge having a first output node and a second output node in order to provide a differential sensor signal, wherein an average value of voltages of the first output node and the second output node to earth forms a first common operating point; a coupling capacitor stage that is coupled to the first output node and the second output node of the xMR sensor bridge; a processing circuit which is connected via the coupling capacitor stage to the xMR sensor bridge and is configured to provide a second common operating point that is different from the first common operating point; and a clock unit which is configured to operate the processing circuit in at least two switching phases, wherein offset components of the processing circuit are detected and stored in a first switching phase at the second operating point and a component derived from the differential sensor signal, based on the second common operating point, is amplified or compared in a second switching phase.
Aspect 2: The circuit according to Aspect 1, wherein the processing circuit is configured to provide a lower or a higher second common operating point.
Aspect 3: The circuit according to any of Aspects 1-2, wherein the processing circuit comprises at least one of the following circuits: a comparator, an amplifier, an analogue-to-digital converter, or a voltage-controlled oscillator or a current-controlled oscillator.
Aspect 4: The circuit according to any of Aspects 1-3, wherein the processing circuit has an auto-zeroing comparator, wherein, in the first switching phase, an offset of the processing circuit is detected and stored via capacitances integrated in the coupling capacitor stage, and wherein, in the second switching phase, a component derived from the differential sensor signal is compared after subtracting the stored offset.
Aspect 5: The circuit according to any of Aspects 1-4, wherein the processing circuit has an auto-zeroing amplifier, wherein an offset of the auto-zeroing amplifier is detected and stored in the first switching phase, and wherein the differential sensor signal is output with an offset-corrected gain in the second switching phase.
Aspect 6: The circuit according to any of Aspects 1-5, wherein the processing circuit is configured according to a correlated double sampling method, wherein, in the first switching phase, a first sample of the differential sensor signal including the offset of the processing circuit is captured, wherein, in the second switching phase, a second, inverted sample of the differential sensor signal including the offset of the processing circuit is captured, and wherein, an amplified, offset-adjusted sensor signal is generated by forming a difference between the first sample and the second, inverted sample.
Aspect 7: The circuit according to any of Aspects 1-6, wherein a supply polarity of the xMR sensor bridge is configured to be switched in two different switching phases of the at least two switching phases using switches, wherein, in the first switching phase, a first supply is connected to an electrical supply device and a second supply connection is connected to earth, and wherein, in the second switching phase, the first supply is coupled to earth and the second supply connection is coupled to the electrical supply device.
Aspect 8: The circuit according to any of Aspects 1-7, further comprising: an additional clock unit which is configured to switch the xMR sensor bridge and/or the processing circuit between an active and an inactive state in a duty cycle mode.
Aspect 9: The circuit according to any of Aspects 1-8, wherein the processing circuit comprises a resistance network and/or current sources connected in parallel.
Aspect 10: The circuit according to any of Aspects 1-9, wherein the processing circuit comprises a switched capacitance network.
Aspect 11: The circuit according to any of Aspects 1-10, wherein the coupling capacitor stage has a first coupling capacitor and a second coupling capacitor each switchably coupled to the first output node and the second output node of the xMR sensor bridge, wherein, in the first switching phase, a first electrode of a coupling capacitor is connected to the first output node of the xMR sensor bridge and a second electrode of the coupling capacitor is connected to an output of the processing circuit, and wherein, in the second switching phase, the second electrode of the coupling capacitor is coupled to an input of the processing circuit.
Aspect 12: The circuit according to any of Aspects 1-11, wherein the processing circuit comprises a reference device which, in the first switching phase, assigns a reference voltage level to a coupling capacitor, which voltage level is different from a common mode voltage of the xMR sensor bridge.
Aspect 13: The circuit according to Aspect 12, wherein the reference device has an electrical resistor which is coupled via a first connection to the coupling capacitor and to an output of the processing circuit and is coupled via a second connection to earth.
Aspect 14: The circuit according to any of Aspects 1-13, wherein the xMR sensor bridge, the coupling capacitor stage, and the processing circuit are monolithically integrated.
Aspect 15: The circuit according to any of Aspects 1-14, wherein the circuit with a sensor is manufactured in a complementary metal-oxide-semiconductor (CMOS) technology.
Aspect 16: The circuit according to any of Aspects 1-15, wherein the xMR sensor bridge is configured as a tunnel magnetoresistance (TMR) sensor bridge.
Aspect 17: The circuit according to any of Aspects 1-16, wherein a supply voltage of the circuit is less than or equal to 1.5 V.
Aspect 18: A method for detecting a magnetic field using a magnetoresistive sensor (xMR) sensor bridge, comprising the steps of: supplying the xMR sensor bridge with a supply voltage, tapping off a first sensor output signal and a second sensor output signal at respective outputs of the xMR sensor bridge, capacitively decoupling a first common mode voltage of the first sensor output signal and the second sensor output signal via at least two coupling capacitors to provide decoupled signals, supplying the decoupled signals to a processing circuit which is operated in at least two switching phases, setting a second common mode voltage, which differs from the first common mode voltage of the xMR sensor bridge, at an input and a output of the at least two coupling capacitors in a first switching phase.
Aspect 19: A circuit for detecting a magnetic field, comprising: a magnetoresistive sensor (xMR) sensor bridge having a first output and a second output for providing a sensor output signal; at least two decoupling capacitors each switchably coupled to the first output and the second output of the xMR sensor bridge; an analogue processing circuit that is connected to the first output and the second output of the xMR sensor bridge via the at least two decoupling capacitors; and at least one clock device for operating the analogue processing circuit in at least two switching phases, including a first switching phase and a second switching phase, wherein the analogue processing circuit is configured to set a voltage differing from a common mode voltage of the xMR sensor bridge at the at least two decoupling capacitors in the first switching phase.
Aspect 20: The circuit according to Claim 19, wherein the analogue processing circuit is configured to amplify a sensor signal transmitted by the at least two decoupling capacitors and/or to compare the sensor signal with a comparison or reference signal in the second switching phase, and wherein a voltage potential set at the at least two decoupling capacitors in the first switching phase and differing from the common mode voltage of the xMR sensor bridge is used to achieve a minimum supply voltage.
Aspect 21: A system configured to perform one or more operations recited in one or more of Aspects 1-20.
Aspect 22: An apparatus comprising means for performing one or more operations recited in one or more of Aspects 1-20.

1. A circuit for detecting a magnetic field, comprising:
a magnetoresistive sensor (xMR) sensor bridge having a first output node and a second output node in order to provide a differential sensor signal, wherein an average value of voltages of the first output node and the second output node to earth forms a first common operating point;
a coupling capacitor stage that is coupled to the first output node and the second output node of the xMR sensor bridge;
a processing circuit which is connected via the coupling capacitor stage to the xMR sensor bridge and is configured to provide a second common operating point that is different from the first common operating point; and
a clock unit which is configured to operate the processing circuit in at least two switching phases, wherein offset components of the processing circuit are detected and stored in a first switching phase at the second operating point and a component derived from the differential sensor signal, based on the second common operating point, is amplified or compared in a second switching phase.

2. The circuit according to claim 1, wherein the processing circuit is configured to provide a lower or a higher second common operating point.

3. The circuit according to claim 1, wherein the processing circuit comprises at least one of the following circuits:
a comparator,
an amplifier,
an analogue-to-digital converter, or
a voltage-controlled oscillator or a current-controlled oscillator.

4. The circuit according to claim 1, wherein the processing circuit has an auto-zeroing comparator,
wherein, in the first switching phase, an offset of the processing circuit is detected and stored via capacitances integrated in the coupling capacitor stage, and
wherein, in the second switching phase, a component derived from the differential sensor signal is compared after subtracting the stored offset.

5. The circuit according to claim 1, wherein the processing circuit has an auto-zeroing amplifier,
wherein an offset of the auto-zeroing amplifier is detected and stored in the first switching phase, and
wherein the differential sensor signal is output with an offset-corrected gain in the second switching phase.

6. The circuit according to claim 1, wherein the processing circuit is configured according to a correlated double sampling method,
wherein, in the first switching phase, a first sample of the differential sensor signal including the offset of the processing circuit is captured,
wherein, in the second switching phase, a second, inverted sample of the differential sensor signal including the offset of the processing circuit is captured, and
wherein, an amplified, offset-adjusted sensor signal is generated by forming a difference between the first sample and the second, inverted sample.

7. The circuit according to claim 1, wherein a supply polarity of the xMR sensor bridge is configured to be switched in two different switching phases of the at least two switching phases using switches,
wherein, in the first switching phase, a first supply is connected to an electrical supply device and a second supply connection is connected to earth, and
wherein, in the second switching phase, the first supply is coupled to earth and the second supply connection is coupled to the electrical supply device.

8. The circuit according to claim 1, further comprising:
an additional clock unit which is configured to switch the xMR sensor bridge and/or the processing circuit between an active and an inactive state in a duty cycle mode.

9. The circuit according to claim 1, wherein the processing circuit comprises a resistance network and/or current sources connected in parallel.

10. The circuit according to claim 1, wherein the processing circuit comprises a switched capacitance network.

11. The circuit according to claim 1, wherein the coupling capacitor stage has a first coupling capacitor and a second coupling capacitor each switchably coupled to the first output node and the second output node of the xMR sensor bridge,
wherein, in the first switching phase, a first electrode of a coupling capacitor is connected to the first output node of the xMR sensor bridge and a second electrode of the coupling capacitor is connected to an output of the processing circuit, and
wherein, in the second switching phase, the second electrode of the coupling capacitor is coupled to an input of the processing circuit.

12. The circuit according to claim 1, wherein the processing circuit comprises a reference device which, in the first switching phase, assigns a reference voltage level to a coupling capacitor, which voltage level is different from a common mode voltage of the xMR sensor bridge.

13. The circuit according to claim 12, wherein the reference device has an electrical resistor which is coupled via a first connection to the coupling capacitor and to an output of the processing circuit and is coupled via a second connection to earth.

14. The circuit according to claim 1, wherein the xMR sensor bridge, the coupling capacitor stage, and the processing circuit are monolithically integrated.

15. The circuit according to claim 1, wherein the circuit with a sensor is manufactured in a complementary metal-oxide-semiconductor (CMOS) technology.

16. The circuit according to claim 1, wherein the xMR sensor bridge is configured as a tunnel magnetoresistance (TMR) sensor bridge.

17. The circuit according to claim 1, wherein a supply voltage of the circuit is less than or equal to 1.5 V.

18. A method for detecting a magnetic field using a magnetoresistive sensor (xMR) sensor bridge, comprising the steps of:
supplying the xMR sensor bridge with a supply voltage,
tapping off a first sensor output signal and a second sensor output signal at respective outputs of the xMR sensor bridge,
capacitively decoupling a first common mode voltage of the first sensor output signal and the second sensor output signal via at least two coupling capacitors to provide decoupled signals,
supplying the decoupled signals to a processing circuit which is operated in at least two switching phases,
setting a second common mode voltage, which differs from the first common mode voltage of the xMR sensor bridge at an input and a output of the at least two coupling capacitors in a first switching phase.

19. A circuit for detecting a magnetic field, comprising:
a magnetoresistive sensor (xMR) sensor bridge having a first output and a second output for providing a sensor output signal;
at least two decoupling capacitors each switchably coupled to the first output and the second output of the xMR sensor bridge;
an analogue processing circuit that is connected to the first output and the second output of the xMR sensor bridge via the at least two decoupling capacitors; and
at least one clock device for operating the analogue processing circuit in at least two switching phases, including a first switching phase and a second switching phase,
wherein the analogue processing circuit is configured to set a voltage differing from a common mode voltage of the xMR sensor bridge at the at least two decoupling capacitors in the first switching phase.

20. The circuit according to claim 19, wherein the analogue processing circuit is configured to amplify a sensor signal transmitted by the at least two decoupling capacitors and/or to compare the sensor signal with a comparison or reference signal in the second switching phase, and
wherein a voltage potential set at the at least two decoupling capacitors in the first switching phase and differing from the common mode voltage of the xMR sensor bridge is used to achieve a minimum supply voltage.
